(19) United States
(12) Patent Application Publication
(10) Pub. No.: US 2021/0335594 A1
(43) Pub. Date: Oct. 28, 2021

(54) METHOD FOR PROCESSING SEMICONDUCTOR STRUCTURE

(71) Applicant: CHANGXIN MEMORY TECHNOLOGIES, INC., Hefei (CN)

(72) Inventor: SHIN-HUNG LEE, Hefei (CN)

(21) Appl. No.: 17/371,027

(22) Filed: Jul. 8, 2021

Related U.S. Application Data
(63) Continuation of application No. PCT/CN2021/079971, filed on Mar. 10, 2021.

(30) Foreign Application Priority Data
Mar. 11, 2020 (CN) 202010166572.2

(51) Int. Cl. H01L 21/02

(52) U.S. Cl. CPC H01L 21/0206; H01L 21/02233; H01L 21/02164

(57) ABSTRACT

The present disclosure relates to the field of semiconductor fabrication technology, and in particular to a method for processing a semiconductor structure, including the following steps: providing a semiconductor structure, the semiconductor structure including a substrate and a plurality of etched structures positioned on the surface region of the substrate; forming a transition layer at least covering the inner walls of the etched structures, the transition layer being configured to reduce a capillary force exerted by a fluid on the etched structures and to serve as a sacrificial layer configured to repair a collapsed structure; drying the semiconductor structure; and removing the transition layer. According to the method provided by the present disclosure, the probability of the collapse or deformation of the etched structures during a cleaning process is reduced, the performance of the semiconductor structure is improved, and the productivity and the yield of the semiconductor devices are increased.

### CROSS-REFERENCE TO RELATED APPLICATIONS

This application is a continuation of PCT/CN2021/079971, filed on Mar. 10, 2021, which claims priority to Chinese Patent Application No. 202010166572.2, titled “METHOD FOR PROCESSING SEMICONDUCTOR STRUCTURE” and filed on Mar. 11, 2020, the entire contents of which are incorporated herein by reference.

### TECHNICAL FIELD

The present disclosure relates to the field of semiconductor production technology, and more particularly, to a method for processing a semiconductor structure.

### BACKGROUND

With the rapid development of the semiconductor industry in recent years, high-aspect-ratio (HAR) nanostructures have been widely used in various fields. As nanometer devices are increasingly pursued in technology, the feature size of chips continues to shrink in a production process, and the entire semiconductor production technology is still developing towards further miniaturization of critical dimensions.

After patterns such as trenches are etched in semiconductor structures such as a Dynamic Random Access Memory (DRAM), steps of wet cleaning and drying are generally required to remove the byproduct generated in the etching process or the residual polymers generated after the etching process. However, in the processes of the wet cleaning and the drying, a capillary action may cause the collapse or deformation of the patterns. The smaller the sizes of the trenches formed by etching are, the greater the tension of the fluid likely appearing in the semiconductor structure is. There are three factors generally causing the collapse of the patterns: Laplace pressure; adhesive force; and electrostatic force, Van der Waals' force, and hydrogen-bond interaction. In an advanced DRAM production process, the collapse of the patterns may seriously affect the yield and productivity rate of the chips, and increasingly becomes a key factor in determining the success or failure of the DRAM production process. Particularly, a HAR Shallow Trench Isolation (STI) structure has more severe collapse or deformation of the patterns due to the capillary action in the wet cleaning. Therefore, it is of vital importance to eliminate or reduce the risk of the collapse of the pattern in the production of semiconductor devices such as the DARM.

However, in the more advanced DRAM production process, with the size of the structure becoming smaller and requirement for HAR, a great challenge is posed to the stability of the liquid environment during cleaning. Therefore, the surface effect of the cleaning liquid becomes a major factor affecting production quality. In some embodiments, the wet cleaning may cause the collapse of the patterns due to the capillary action on the pattern structures. The occurrence of the collapse of the patterns may be reduced by means of surface finishing of the HAR structure. However, this treatment method may lead to other negative effects, such as the super-hydrophobic effect of the HAR structure. This super-hydrophobic effect may prevent the aqueous solution from penetrating into the structure, resulting in a decrease in the effect of wet cleaning. In addition, taking the STI production as an example, a surface finishing agent is added after the wet cleaning before the drying process, which can effectively prevent the occurrence of pattern collapse. However, the surface finishing agent may remain at the bottom of the STI structure, which may cause abnormalities of the semiconductor devices.

Therefore, it is a technical problem to be solved urgently at present how to reduce the occurrence of pattern collapse or deformation in the wet cleaning process of the semiconductor structures to improve the performance of the semiconductor structures and increase the yield of the semiconductor devices.

### SUMMARY

The present disclosure provides a method for processing a semiconductor structure. This method is used for solving the problem of pattern collapse or deformation prone to occur in a cleaning process of the semiconductor structure, to improve the performance of the semiconductor structure and increase the yield of the semiconductor devices.

To solve the above problem, the present disclosure provides a method for processing a semiconductor structure, comprising:

providing a semiconductor structure, the semiconductor structure comprising a substrate and a plurality of etched structures arranged on a surface area of the substrate;

forming a transition layer at least covering inner walls of the plurality of etched structures, the transition layer being configured to reduce a capillary force exerted by a fluid on the etched structures and to serve as a sacrificial layer configured to repair a collapsed structure;

drying the semiconductor structure; and

removing the transition layer.

In some embodiments, the plurality of etched structures are trenches, and number of the trenches arranged on the surface area of the substrate is more than one.

The ratio of the depth of each of the trenches to the minimum width of the trenches is greater than 8.

In some embodiments, the trenches are arranged in parallel on the surface area of the substrate.

The width of the pattern line between two adjacent ones of the trenches is less than 20 nm.

In some embodiments, the step of providing a semiconductor structure may include:

providing the substrate;

etching the substrate to form the trenches on the surface area of the substrate, bottoms of the trenches extending into the substrate to form the semiconductor structure; and

cleaning the semiconductor structure to remove impurities generated after the trenches are formed by etching.

In some embodiments, the step of cleaning the semiconductor structure comprises:

processing the semiconductor structure by means of a plasma ashing process to remove polymer residue generated after the trenches are formed by etching; and

processing the semiconductor structure by means of a wet cleaning process to remove by-product and pollutant generated after the etching and the plasma ashing processes.

In some embodiments, the step of processing the semiconductor structure by means of the plasma ashing process comprises the following specific step:

performing the plasma ashing process on a surface of the semiconductor structure by means of plasmonized oxygen to remove the polymer residue generated after the trenches are formed by the etching.

In some embodiments, the ratio of the flow of oxygen to the flow of the mixed gas composed of hydrogen and nitrogen is 10:1, and the volume ratio of the hydrogen in the mixed gas composed of the hydrogen and the nitrogen is 4%.

In some embodiments, the step of forming a transition layer at least covering the inner walls of the etched structures comprises the following specific step:

oxidizing the semiconductor structure to form an oxide layer at least covering the inner walls of the trenches, the oxide layer being the transition layer.

In some embodiments, oxidizing the semiconductor structure comprises the following specific step:

processing the semiconductor structure by means of an oxidizing liquid, the oxidizing liquid at least filling up the trenches.

The oxidizing liquid is ozonated water or a mixed solution composed of ammonia water and hydrogen peroxide.

In some embodiments, processing the semiconductor structure by means of an oxidizing liquid comprises the following specific step:

spraying the oxidizing liquid to a surface of the semiconductor structure being spinning to rinse the semiconductor structure.

In some embodiments, the oxide layer has a thickness of 2 Å to 12 Å.

In some embodiments, removing the transition layer comprises the following specific step:

removing the transition layer by means of a mixed gas comprising hydrogen fluoride and ammonia gas as etching gas.

In some embodiments, the substrate and the transition layer removed by the etching by means of the mixed gas comprising the hydrogen fluoride and the ammonia gas as the etching gas have a total thickness of 1 nm to 10 nm.

In some embodiments, the ratio of the flow of the hydrogen fluoride to the flow of the ammonia gas is (1˜2):1.

In some embodiments, drying the semiconductor structure comprises the following specific step:

processing the semiconductor structure by means of isopropanol at a preset temperature to remove moisture on the surface area of the semiconductor structure.

In some embodiments, after removing the transition layer, the method further comprises the following step:

purging the semiconductor structure by means of a gas.

By using the method for processing a semiconductor structure provided by the present disclosure, a transition layer configured to reduce the capillary force exerted by a fluid on the etched structures is formed on the inner walls of the etched structures such that the probability of collapse or deformation of the etched structures is reduced in the subsequent process of drying the etched structures. Furthermore, the transition layer covering the inner walls of the etched structures is removed after being dried, so the attraction force between the patterns of the etched structures is broken such that the etched structures deformed in the previous drying process is restored to its original state, thereby further reducing the probability of collapse or deformation of the etched structures, improving the performance of the semiconductor structure, and increasing the productivity and the yield of the semiconductor devices.

### BRIEF DESCRIPTION OF THE DRAWINGS

FIG. 1 is a flowchart of a method for processing a semiconductor structure according to embodiments of the present disclosure;

FIG. 2A-FIG 2F are schematic diagrams showing major technologies during processing a semiconductor structure according to embodiments of the present disclosure;

FIG. 3A-FIG 3E are schematic diagrams showing major technologies during processing another semiconductor structure according to embodiments of the present disclosure; and

FIG. 4A-FIG. 4H are schematic sectional views of a processing chamber during processing a semiconductor structure according to embodiments of the present disclosure.

### DETAILED DESCRIPTION

A specific embodiment of a method for processing a semiconductor structure provided by the present disclosure is described in detail below with reference to the accompanying drawings.

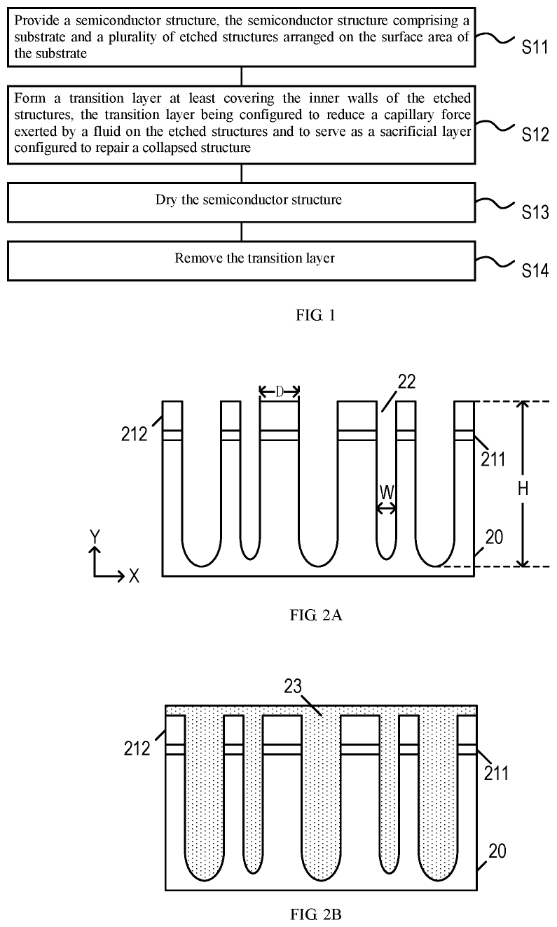

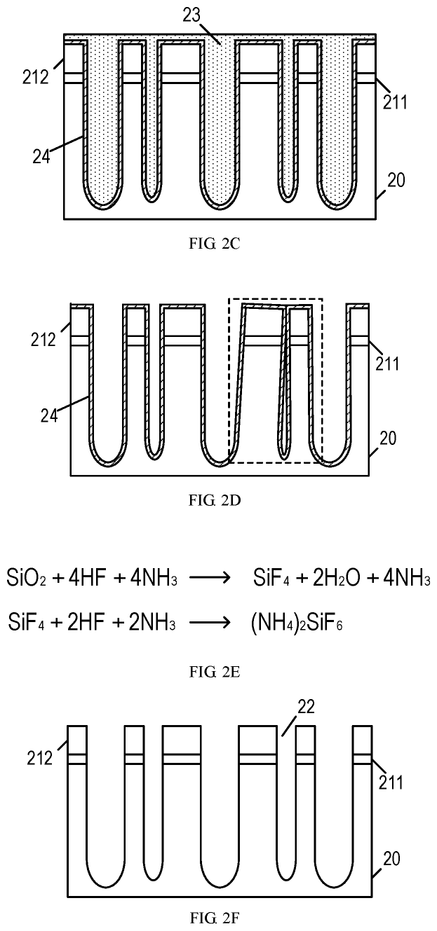

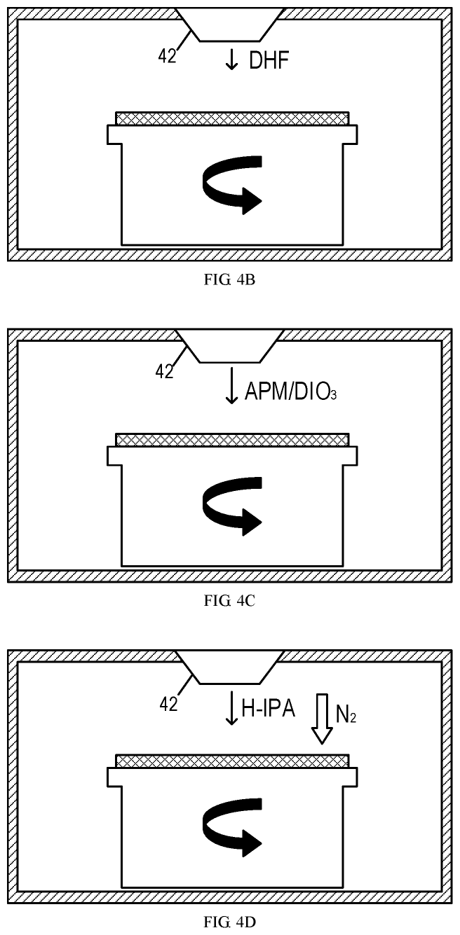

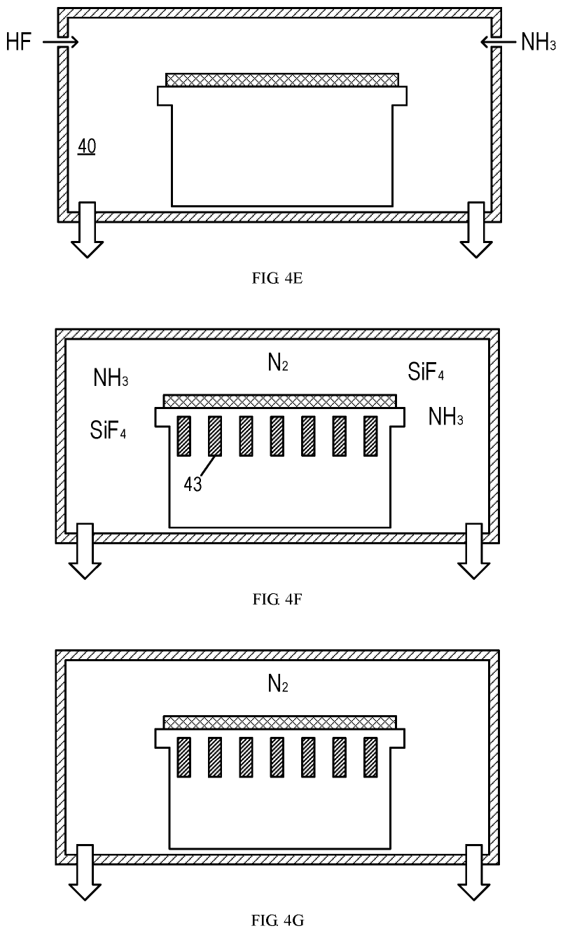

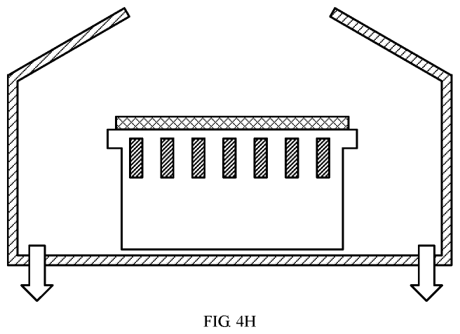

This specific embodiment provides a method for processing a semiconductor structure. FIG. 1 is a flowchart of the method for processing a semiconductor structure according to this specific embodiment of the present disclosure. FIG. 2A-FIG. 2F are schematic diagrams showing major technologies during processing a semiconductor structure according to this specific embodiment of the present disclosure. FIG. 4A-FIG 4H are schematic sectional views of a processing chambers during processing a semiconductor structure according to this specific embodiment of the present disclosure. As shown in FIG. 1, FIG. 2A-FIG 2F, and FIG. 4A-FIG. 4H, the method for processing a semiconductor structure provided by this specific embodiment includes following steps.

Step S11, providing a semiconductor structure, wherein the semiconductor structure comprises a substrate 20 and a plurality of etched structures 22 arranged on the surface area of the substrate 20, as shown in FIG. 2A.

In this specific embodiment, the etched structures 22 may be any structures formed on the substrate 20 by means of a dry etching process. In some embodiments, the etched structures are trenches, and the number of the trenches arranged on the surface area of the substrate is more than one.

The ratio of the depth H of the trench to the minimum width W of the trench is greater than 8.

In some embodiments, the trenches are arranged in parallel on the surface area of the substrate 20.

The width D of the pattern line between two adjacent ones of the trenches is less than 20 nm.

In some embodiments, the etched structures 22 may be trenches such as shallow trench isolation (STI) extending from the surface of the substrate 20 into the substrate 20 along the direction (i.e., the Y-axis direction in FIG. 2A) perpendicular to the substrate 20. In semiconductor production processes, trenches with higher aspect ratio (HAR) are more likely to collapse or deform during the cleaning process. The method for processing a semiconductor structure provided in this embodiment is more effective in preventing the collapse or deformation of the trenches with higher aspect ratio during the cleaning process. FIG. 2A shows five trenches arranged in parallel on the surface area of the substrate 20 (i.e., the Y-axis direction in FIG. 2A). In practical use, the specific number of the trenches may be determined by the person skilled in the art according to actual needs. The aspect ratios of the plurality of trenches may be same or different. The term “a plurality of” in this specific embodiment means two or more.

In some embodiments, the step of providing a semiconductor structure includes:

providing a substrate 20;

etching the substrate 20 to form the plurality of trenches on the surface area of the substrate 20, the bottoms of the trenches extending into the substrate 20 to form the semiconductor structure; and

cleaning the semiconductor structure to remove the impurities after forming the trenches by etching.

In some embodiments, cleaning the semiconductor structure comprises the following specific steps:

processing the semiconductor structure by means of a plasma ashing process to remove the polymer residue after forming the trenches by etching; and

processing the semiconductor structure by means of a wet cleaning process to remove the by-product and the pollutant generated after the etching and ashing processes.

In some embodiments, processing the semiconductor structure by means of the plasma ashing process comprises the following specific steps:

performing the ashing process on the surface of the semiconductor structure by means of plasmonized oxygen to remove the polymer residue generated after the trenches are formed by the etching.

In some embodiments, performing the ashing process on the surface of the semiconductor structure by means of the plasmonized oxygen comprises the following specific step:

simultaneously introducing the plasmonized oxygen and a mixed gas composed of hydrogen and nitrogen, wherein the ratio of the flow of the oxygen to the flow of the mixed gas is 10:1. The volume ratio of the hydrogen in the mixed gas composed of the hydrogen and the nitrogen is 4%.

In some embodiments, the surface of the substrate 20 has a mask layer, such as a first mask layer 211 covering the surface of the substrate 20 and a second mask layer 212 covering the surface of the first mask layer 211 in FIG. 2A. The mask layer has a mask pattern. After the substrate 20 is etched using dry etching process or other etching processes along the mask pattern in the mask layer to form the trenches, some polymers (i.e., the polymer residue) may remain inside the trenches. Some by-products and pollutants may also be generated by the etching reaction between the etchant and the substrate 20. To avoid causing adverse effects on subsequent processes, in this specific embodiment, after etching the trench, the polymer residue is first removed by using the plasma ashing process, and then the by-products and the pollutants are removed by using wet cleaning process, to make sure the inside of the trenches and the surface of the substrate clear. The material of the first mask layer 211 may be silicon oxide, and the material of the second mask layer 212 may be silicon nitride.

In the plasma ashing process, the flow rate of the oxygen is 5,000 ml/min˜30,000 ml/min, the flow rate of the mixed gas composed of the hydrogen and the nitrogen (the volume ratio of the hydrogen is 4%) is 500 ml/min˜3,000 ml/min, the temperature is 100° C.˜500° C., the duration is 10 s˜120 s, the pressure in the processing chamber is of 200 mtorr˜5,000 mtorr, and the radio frequency (RF) power is of 1,000 W˜10,000 W. In wet cleaning process, the cleaning agent may be diluted HF (DHF), wherein the volume ratio of the HF (49% HF liquid) to the deionized water is 1:(1˜1000), the duration is 5 s˜600 s, the temperature is 15° C.˜60° C., and the rotation speed of the support platform is 100 rpm˜3,000 rpm.

For example, after the trenches are etched, the substrate 20 having the trench is placed onto the support platform 41 in the processing chamber 40 as shown in FIG. 4A. In the plasma ashing process, a spray head 42 sprays the plasmonized oxygen to the substrate 20 at a flow rate of 13,000 ml/min, and simultaneously sprays the plasmonized mixed gas (the mixed gas is composed of the hydrogen and the nitrogen, and the volume ratio of the hydrogen is 4%) to the substrate at the flow rate of 1,300 ml/min, the temperature in the processing chamber 40 is maintained at 250° C., the pressure is 1,200 mtorr, the RF power is 4,400 W, and the duration is 21 s. After the plasma ashing process is completed, in wet cleaning process, the DHF (1:200) is used as the cleaning agent, as shown in FIG. 4B. The cleaning agent is sprayed onto the surface of the substrate 20 through the spray head 42, meanwhile the support platform 41 rotates at the speed of 1,500 rpm, the temperature is room temperature, and the duration is 130 s.

Step S12, forming a transition layer 24 at least covering the inner walls of the etched structures 22, where the transition layer 24 is configured to reduce a capillary force exerted by a fluid on the etched structures 22, as shown in FIG. 2C.

In some embodiments, forming a transition layer 24 at least covering the inner walls of the etched structures 22 comprises the following specific step:

oxidizing the semiconductor structure to form an oxide layer at least covering the inner walls of the trenches, wherein the oxide layer is the transition layer 24.

In some embodiments, oxidizing the semiconductor structure comprises the following specific step:

processing the semiconductor structure by means of an oxidizing liquid, wherein the oxidizing liquid at least fills up the trenches, as shown in FIG. 2B.

The oxidizing liquid is an ozone deionized aqueous solution (DIO₃) or a mixed solution (i.e., APM solution) composed of ammonia water and hydrogen peroxide solution.

In some embodiments, processing the semiconductor structure by means of the oxidizing liquid comprises the following step:

spraying the oxidizing liquid to the surface of the semiconductor structure being spinning to rinse the semiconductor structure.

In some embodiments, the oxide layer has a thickness of 2 Å to 12 Å.

In some embodiments, after the semiconductor structure is cleaned, as shown in FIG. 4C, the ozone deionized aqueous solution or the APM solution may be sprayed to the substrate 20 through the spray head 42, while the support platform keeps spinning. For example, when the oxidizing liquid is the ozone deionized aqueous solution, the flow rate of O₃ mixed into the deionized water is 1 L/min˜10 L/min, the flow rate of the ozone deionized aqueous solution is 1 L/min˜10 L/min, the process temperature is 5 ° C.˜35 ° C., the process duration is 6 s˜1,800 s, the rotation speed of the support platform is 100 rpm˜1,200 rpm, and the thickness of the oxide layer formed is 2 Å˜12 Å. When the oxidizing liquid is the APM solution, the volume ratio of NH₄OH, H₂O₂ and H₂O in the APM solution is NH₄OH:H₂O₂:H₂O=1:(1˜10):(10˜200)(as an example: NH₄OH:H₂O₂:H₂O=1:7:58), the temperature is 20° C.˜65° C., the duration is 10 s˜600 s, the process conditions such as the flow rate of the APM solution and the rotation speed of the support platform may be the same as those needed when the ozone deionized aqueous solution is used as an oxidizing solution. The oxide layer formed has 2 Å˜12 Å of a thickness. The person skilled in the art may adjust the thickness of the generated transition layer 24 by adjusting the process conditions.

When the material of the substrate 20 is silicon, the material of the transition layer 24 is silicon dioxide. Due to the transition layer 24 formed in the semiconductor structure, the transition layer 24 can be prevented from serving as the interface layer between the silicon and the fluid in the subsequent semiconductor rinsing process, such that the resistance of the trenches to the tension of the fluid can be enhanced, i.e., the capillary force exerted by the fluid on the trenches can be reduced. In this way, the pattern structures such as the trenches may be protected. Additionally, the transition layer 24 (such as the oxide layer) may also change the hydrophobicity of the semiconductor structure, thereby reducing the Van der Waals' force exerted by the silicon surface on the particulates, such that it is more advantageous to removing the particulates inside the etched structures such as the trenches.

Step S13, drying the semiconductor structure, as shown in FIG. 2D.

In some embodiments, drying the semiconductor structure comprises the following specific step:

processing the semiconductor structure by means of isopropanol at a preset temperature to remove the moisture on the surface area of the semiconductor structure.

In some embodiments, as shown in FIG. 4D, hot isopropanol (Hot-IPA) is used as a drying fluid. In one aspect, the Hot-IPA can remove the moisture on the surface area of the semiconductor structure, and in another aspect, it can also help to further reduce the surface tension. The drying fluid is sprayed onto the surface of the semiconductor structure through the spray head 42, and at the same time, the nitrogen is introduced, as the purge gas, into the processing chamber to purge the isopropanol away through the exhaust port of the processing chamber. In this way, the semiconductor structure is dried. The flow rate of the isopropanol is 50 ml/min˜500 ml/min, the temperature is 40° C.˜80° C., the duration is 10 s˜600 s, and the rotation speed of the support platform is 100 rpm˜4,000 rpm. The temperature is preset at 40° C.˜80° C., for example 60° C.

Step S14, removing the transition layer 24, as shown in FIG. 2F.

In the drying process, due to the effect of the surface energy of the membrane layer on the surface of the wafer, electrostatic friction may be released and/or the attraction between molecules may be applied, and the top of the etched structure is more fragile than the bottom thereof, so the etched structures is prone to tilt at the top due to the aforementioned forces, as shown in the dashed box in FIG. 2D. However, within the elastic limit, after the transition layer 24 is removed, the attraction between the etched structures is broken, and the etched patterns may bounce off thanks to restoring force to restore to its original state, as shown in FIG. 2F.

In some embodiments, removing the transition layer 24 comprises the following specific step:

removing the transition layer 24 by means of a mixed gas composed of hydrogen fluoride (99.999% HF gaseous) and ammonia gas as the etching gas.

In some embodiments, the substrate 20 and the transition layer 24 removed by the etching by means of the mixed gas composed of the hydrogen fluoride and the ammonia gas as the etching gas have a total thickness of 1 nm to 10 nm.

In some embodiments, the ratio of the flow of the hydrogen fluoride to the flow of the ammonia gas is (1˜2):1.

In some embodiments, as shown in FIG. 4E and 4F, HF and NH₃ are simultaneously introduced into the processing chamber, and the transition layer 24 is removed by means of a vapor etching method. Taking as an example where the material of the transition layer 24 is silicon dioxide, the chemical reaction occurring in the process of etching the silicon dioxide by HF and NH₃ is as shown in FIG. 2E. In the process of removing the transition layer, the exhaust gas produced in the reaction process is drawn away in time through the exhaust port at the bottom of the processing chamber, as shown by the arrows in FIG. 4E and FIG. 4F. In the process of etching the transition layer 24, a ratio of the flow of HF to the flow of NH₃ is (1˜2):1. The flow rate of HF and the NH₃ is 10 sccm˜300 sccm (for example, 25 sccm), the temperature is 20° C.˜150° C. (for example, 130° C.), and the duration is 1 s˜60 s, the pressure in the processing chamber is 1 mtorr˜5,000 mtorr and the temperature of the support platform is 20° C.˜150° C. (for example, 35° C.). In this step, the transition layer 24 is over-etched to fully remove the transition layer, such that the etched structures deformed in the drying process by using the isopropanol can be restored to the greatest extent. The thickness of the transition layer 24 etched away may be 1 nm to 10 nm. In the process of removing the transition layer 24 in this step, the process of alternately and cyclically introducing NH₃/HF and N₂ may also be adopted. For example, HF and NH₃ are introduced in the first stage, N₂ is introduced in the second stage, HF and NH₃ are introduced in the third stage, N₂ is introduced in the fourth stage . . . , and so on alternately.

In some embodiments, after removing the transition layer 24, the method further comprises the following step:

purging the semiconductor structure by means of a gas, as shown in FIG. 4G and FIG. 4H.

In some embodiments, after the process of etching the transition layer 24 is completed, in one aspect, a heater 43 inside the support platform is used to heat the substrate 20 to evaporate the products generated in the etching reaction. In another aspect, the nitrogen is introduced into the processing chamber and the processing chamber is continuously evacuated, such that the residues generated after the etching reaction are discharged from the processing chamber in time. Finally, the processing chamber is further purged by means of the nitrogen, as shown in FIG. 4G; until the support platform stops spinning, and the entire wet cleaning process is completed, as shown in FIG. 4H. In the process of gas purging the semiconductor structure by means of the gas, the flow rate of the nitrogen is 200 sccm˜10,000 sccm (for example, 2,000 sccm). The temperature of the wet cleaning is 90° C.˜250° C. (for example, 95° C.), the duration is 20 s˜600 s(for example, 120 s), the pressure of the processing chamber is 200 mtorr˜10,000 mtorr (for example, 2,000 mtorr).

By using the method for processing a semiconductor structure provided in this embodiment, when the depth H of the trench is 300 nm or 310 nm, the probability of occurrence of collapse or deformation of the pattern after the cleaning process is less than 2%.

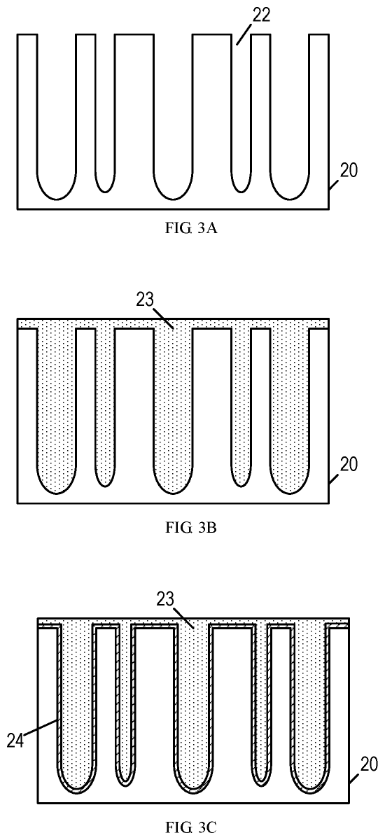

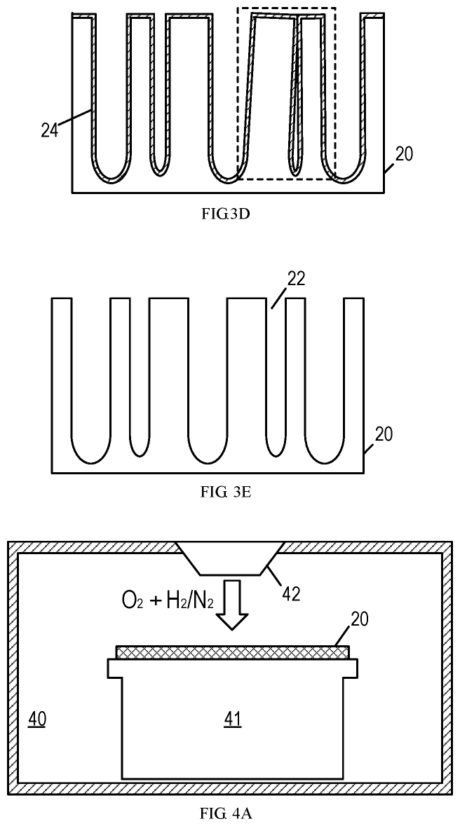

FIGS. 2A-2F show a method for processing a semiconductor structure where an etched structures is formed by a mask layer. In other specific embodiments, during processing, the surface of the substrate 20 may also have no mask layer. FIG. 3A-FIG 3E are schematic diagrams showing major technologies during processing another semiconductor structure according to embodiments of the present disclosure. That is, FIG. 3A-FIG. 3E illustrate schematic diagrams of processing the semiconductor structure having no mask layer on the surface of the substrate. The processing steps and the process conditions during the implementation of each of the processing steps may be the same as the conditions as shown in FIG. 2A to FIG. 2F and FIG. 4A to FIG. 4H.

By using the method for processing a semiconductor structure provided by this embodiment of the present disclosure, the transition layer configured to reduce the capillary force exerted by the fluid on the etched structures is formed on the inner walls of the etched structures, such that the probability of collapse or deformation of the etched structures is reduced in the subsequent process of drying the etched structures. Furthermore, the transition layer covering the inner walls of the etched structures is removed after being dried, and the attraction between the patterns of the etched structures is broken, such that the etched structures deformed in the previous drying process is restored to its original state, thereby further reducing the probability of collapse or deformation of the etched structures In this way, the performance of the semiconductor structure is improved, and the productivity and the yield of the semiconductor devices are increased.

What is mentioned above merely refers to some embodiments of the present disclosure. It shall be pointed out that to those of ordinary skill in the art, various improvements and embellishments may be made without departing from the principle of the present disclosure, and these improvements and embellishments are also deemed to be within the scope of protection of the present disclosure.

What is claimed is:

1. A method for processing a semiconductor structure, comprising:
providing a semiconductor structure, the semiconductor structure comprising a substrate and a plurality of etched structures arranged on a surface area of the substrate;
forming a transition layer at least covering inner walls of the plurality of etched structures, the transition layer being configured to reduce a capillary force exerted by a fluid on the etched structures and to serve as a sacrificial layer configured to repair a collapsed structure;
drying the semiconductor structure; and
removing the transition layer.

2. The method for processing a semiconductor structure according to claim 1, wherein the plurality of etched structures are trenches, and number of the trenches arranged on the surface area of the substrate is more than one; and
wherein ratio of depth of each of the trenches to minimum width of each of the trenches is greater than 8.

3. The method for processing a semiconductor structure according to claim 2, wherein the trenches are arranged in parallel on the surface area of the substrate; and
wherein width of pattern line between two adjacent ones of the trenches is less than 20 nm.

4. The method for processing a semiconductor structure according to claim 2, wherein providing a semiconductor structure comprises:
providing the substrate;
etching the substrate to form the trenches on the surface area of the substrate, bottoms of the trenches extending into the substrate to form the semiconductor structure; and
cleaning the semiconductor structure to remove impurities generated after the trenches are formed by the etching.

5. The method for processing a semiconductor structure according to claim 4, wherein cleaning the semiconductor structure comprises:
processing the semiconductor structure by means of a plasma ashing process to remove polymer residue generated after the trenches are formed by the etching; and
processing the semiconductor structure by means of a wet cleaning process to remove byproduct and pollutant generated after the etching and the plasma ashing processes.

6. The method for processing a semiconductor structure according to claim 5, wherein processing the semiconductor structure by means of a plasma ashing process comprises:
performing the plasma ashing process on a surface of the semiconductor structure by means of plasmonized oxygen to remove the polymer residue generated after the trenches are formed by the etching.

7. The method for processing a semiconductor structure according to claim 2, wherein forming a transition layer at least covering inner walls of the plurality of etched structures comprises:
oxidizing the semiconductor structure to form an oxide layer at least covering inner walls of the trenches, the oxide layer being the transition layer.

8. The method for processing a semiconductor structure according to claim 7, wherein oxidizing the semiconductor structure comprises:
processing the semiconductor structure by means of an oxidizing liquid, the oxidizing liquid at least filling up the trenches, and the oxidizing liquid being an ozone deionized aqueous solution or a mixed solution of ammonia water and hydrogen peroxide.

9. The method for processing a semiconductor structure according to claim 8, wherein processing the semiconductor structure by mean of an oxidizing liquid comprises:
spraying the oxidizing liquid to a surface of the semiconductor structure being spinning to rinse the semiconductor structure.

10. The method for processing a semiconductor structure according to claim 7, wherein the oxide layer has a thickness of 2 Å to 12 Å.

11. The method for processing a semiconductor structure according to claim 7, wherein removing the transition layer comprises:
removing the transition layer by means of a mixed gas comprising hydrogen fluoride and ammonia gas as etching gas.

12. The method for processing a semiconductor structure according to claim 11, wherein a total thickness of the substrate and the transition layer removed by the etching by means of the mixed gas comprising the hydrogen fluoride and the ammonia gas as the etching gas is 1 nm to 10 nm.

13. The method for processing a semiconductor structure according to claim 11, wherein flow ratio of the hydrogen fluoride to the ammonia gas is (1˜2):1.

14. The method for processing a semiconductor structure according to claim 2, wherein drying the semiconductor structure comprises:
processing the semiconductor structure by means of isopropanol at a preset temperature to remove moisture on a surface area of the semiconductor structure.

15. The method for processing a semiconductor structure according to claim 1, wherein after removing the transition layer, the method further comprises:
purging the semiconductor structure by means of a gas.
